(19) United States
(12) Patent Application Publication
(10) Pub. No.: US 2015/0070967 A1
(43) Pub. Date: Mar. 12, 2015

(54) MEMORY SYSTEM AND METHOD OF MANUFACTURING MEMORY SYSTEM

(71) Applicant: Kabushiki Kaisha Toshiba, Minato-ku (JP)

(72) Inventor: Haruki TODA, Yokohama-shi (JP)

(73) Assignee: Kabushiki Kaisha Toshiba, Minato-ku (JP)

(21) Appl. No.: 14/078,948

(22) Filed: Nov. 13, 2013

Related U.S. Application Data
(60) Provisional application No. 61/875,788, filed on Sep. 10, 2013.

(51) Int. Cl. G11C 13/00; H01L 29/66

(52) U.S. Cl. CPC G11C 13/0069; H01L 29/66742
USPC 365/148; 365/189.16; 438/158

(57) ABSTRACT

A memory system according to the embodiment comprises a cell array including plural unit cell arrays stacked, each unit cell array containing plural first lines, plural second lines intersecting the plural first lines, and plural memory cells provided at the intersections of the plural first lines and the plural second lines; and an access circuit operative to write data in the memory cell, wherein the access circuit partly has a first part formed at the same height as that of a certain unit cell array in the stacking direction of the plural unit cell arrays and on the periphery of the certain unit cell array.

### CROSS-REFERENCE TO RELATED APPLICATIONS

This application is based upon and claims the benefit of priority from the prior U.S. Provisional Application 61/875,788, filed on Sep. 10, 2013, the entire contents of which are incorporated herein by reference.

### BACKGROUND

1. Field

The embodiment of the present invention relates to a memory system and a method of manufacturing a memory system.

2. Description of the Related Art

As memories capable of storing mass data for use, variable resistance memories including cell arrays easily formable in three dimensions, such as a ReRAM (Resistance RAM) and an ion memory, have received attention. In this case, a cell array includes memory cells of the cross point type. The use of the cell array thus structured expands peripheral circuits such as selection line decoders and drivers.

In consideration of the production cost of a chip, it is important to increase the area occupied by memory cells in (the cell share of) the entire chip area. Therefore, the array size of the cell array is two-dimensionally expanded as large as possible. In this case, the number of memory cells increases two-dimensionally while the area of peripheral circuits only increases one-dimensionally around the cell array. As a result, the cell share can be improved.

A variable resistance memory including a cell array of the cross point type is characterized in unit cell arrays stacked to configure a mass cell array. In the conventional case, however, the area of peripheral circuits also increases two-dimensionally in accordance with the increase in the number of unit cell arrays as they are stacked. In this case, as the chip size suffers a large influence, the three-dimensionally structured cell array cannot be utilized sufficiently as a problem.

### BRIEF DESCRIPTION OF THE DRAWINGS

FIG. 1 is a diagram showing a configuration of a memory system according to the embodiment.

FIG. 2 is a perspective view showing part of a cell array in the memory system according to the embodiment.

FIG. 3 is a perspective view showing a configuration of a selection line driver in the memory system according to the embodiment.

FIG. 4 is a diagram showing a layout example of TFTs on a MAT in the memory system according to the embodiment.

FIG. 5 is a cross-sectional view showing a step of forming the selection line driver in order of step in the memory system according to the embodiment.

FIG. 6 is a cross-sectional view showing a step of forming the selection line driver in order of step in the memory system according to the embodiment.

FIG. 7 is a cross-sectional view showing a step of forming the selection line driver in order of step in the memory system according to the embodiment.

FIG. 8 is a cross-sectional view showing a step of forming the selection line driver in order of step in the memory system according to the embodiment.

FIG. 9 is a cross-sectional view showing a step of forming the selection line driver in order of step in the memory system according to the embodiment.

FIG. 10 is a cross-sectional view showing a step of forming the selection line driver in order of step in the memory system according to the embodiment.

FIG. 11 is a diagram illustrative of access operation in a pseudo-FA method in the memory system according to the embodiment.

FIG. 12 is a diagram showing functional blocks of a TILE and peripheral circuits in the memory system according to the embodiment.

FIG. 13 is a circuit diagram of a BL drv circuit block in the memory system according to the embodiment.

FIG. 14 is a circuit diagram of a selection line driver for the word line in the memory system according to the embodiment.

FIG. 15 is a circuit diagram of a drvSEL circuit block in the memory system according to the embodiment.

FIG. 16 is a diagram showing a layout of the BL dry circuit block in the memory system according to the embodiment.

### DETAILED DESCRIPTION

A memory system according to the embodiment comprises a cell array including plural unit cell arrays stacked, each unit cell array containing plural first lines, plural second lines intersecting the plural first lines, and plural memory cells provided at the intersections of the plural first lines and the plural second lines; and an access circuit operative to write data in the memory cell, wherein the access circuit partly has a first part formed at the same height as that of a certain unit cell array in the stacking direction of the plural unit cell arrays and on the periphery of the certain unit cell array.

The following description is given to a memory system and a method of manufacturing a memory system according to the embodiment with reference to the drawings.

First, a configuration of the memory system according to the embodiment is described.

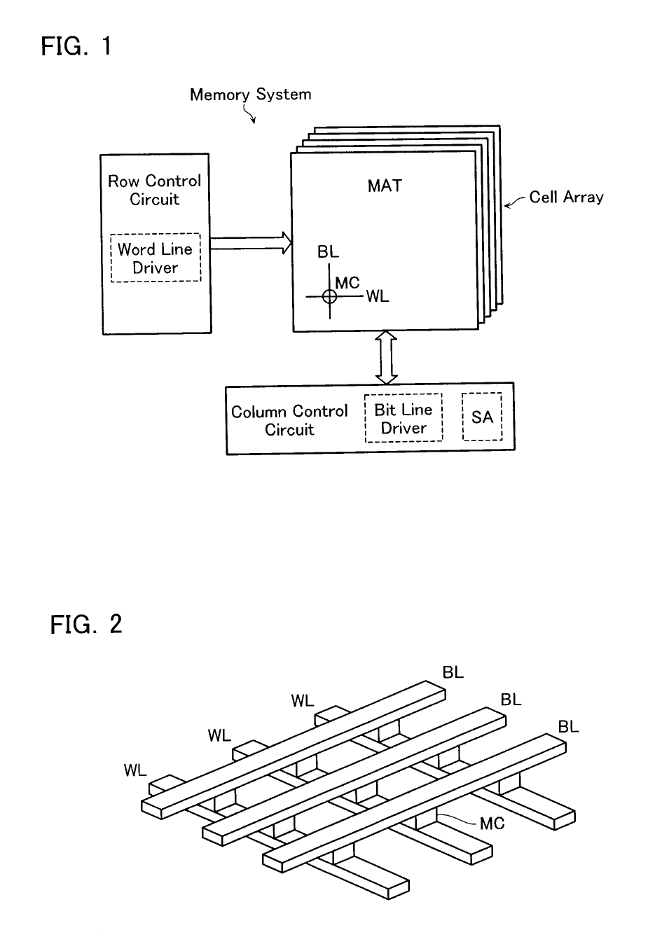

FIG. 1 is a diagram showing the configuration of the memory system according to the embodiment.

This memory system includes a cell array. The cell array includes plural unit cell arrays (hereinafter referred to as “MATs”). Each MAT has plural bit lines BL (first lines) and plural word lines WL (second lines), and plural memory cells MC that can be selected by plural bit lines BL and plural word lines WL.

The bit lines BL in the cell array are electrically connected to a column control circuit, which controls the bit lines BL to write data in the memory cell MC and read data out of the memory cell MC. The column control circuit includes a bit line driver operative to provide the bit line BL with potentials required for data write and data read, and a sense amp SA operative to sense and amplify the current flowing in the memory cell MC (hereinafter referred to as “cell current”) at the time of data read to decide the data stored in the memory cell MC.

On the other hand, the word lines WL in the cell array are electrically connected to a row control circuit, which selects the word line WL at the time of writing data to the memory cell MC and reading data from the memory cell MC. The row control circuit includes a word line driver operative to provide the word line WL with potentials required for data write and data read. The row control circuit is contained in an access circuit together with the column control circuit.

Hereinafter, writing data to the memory cell MC may also be referred to as “write operation”, and a series of processing for realizing the write operation as a “write sequence”. Similarly, reading data from the memory cell MC may also be referred to as “read operation”, and a series of processing for realizing the read operation as a “read sequence”. The write and read operations may also be called by their generic term, that is, “access operation”. In addition, bit lines BL and word lines WL may also be called by their generic term, that is, “selection lines”. A memory cell MC targeted to access operation may also be referred to as an “access cell”, and other memory cells MC as “non-access cells”. Selection lines and so forth connected to the access cell may also be referred to as “access selection lines” and so forth, and other selection lines and so forth as “non-access selection lines” and so forth.

Next, a structure of the memory cell MC is described.

FIG. 2 is a perspective view showing part of a cell array in the memory system according to the embodiment.

The cell array includes plural bit lines BL extending in the column direction, plural word lines WL extending in the row direction, and plural memory cells MC provided at the intersections of plural bit lines BL and plural word lines WL. Thus, the memory cell MC has a structure of the cross point type. Hereinafter, memory cells MC contained in the cell array of the cross point type may also be referred to as “CP cells”.

A mass cell array configured in three dimensions can be formed by stacking MATs of the cross point type. In this case, the cell array can be formed by only repeating the same process, with the merits on the production in easy fault analysis and easy productivity improvement. In contrast, however, in proportion to the number of stacked MATs, an increase arises in area occupied by an access circuit on a semiconductor substrate and thus the cell share of the memory system cannot be increased as a problem. This is caused by the fact that transistors contained in the access circuit are provided on the semiconductor substrate.

Therefore, in the embodiment, the access circuit is composed of thin film transistors (hereinafter referred to as “TFTs”), which are not required to be provided on the semiconductor substrate, and which use an oxide semiconductor or nanotubes to configure a conduction channel.

A part (first part) of a selection line driver in the access circuit is composed of a thin film transistor. This thin film transistor is arranged on a periphery of a MAT in the same layer as the MAT. Thus, the area occupied by the access circuit on the semiconductor substrate can be made smaller to the extent of the selection line driver. Further, in accordance with the increase in the number of MATs, the number of selection line drivers also increases. In the case of the embodiment, though, in addition to MATs, selection line drivers required for the MATs can also be stacked. Therefore, the area occupied by the access circuit on the semiconductor substrate does not increase. As a result, in accordance with the embodiment, the effect of improving the cell share by stacking MATs can be exerted easily. Further, in the case of the embodiment, it is possible to sharply reduce vertical lines for connecting between peripheral circuits on the semiconductor substrate and each MAT. As a result, in accordance with the embodiment, the flexibility of circuits configured on the semiconductor substrate can be improved remarkably. The following description is given to a configuration of a specific memory system using TFTs to configure selection line drivers.

Next, a configuration of the selection line driver using TFTs is described.

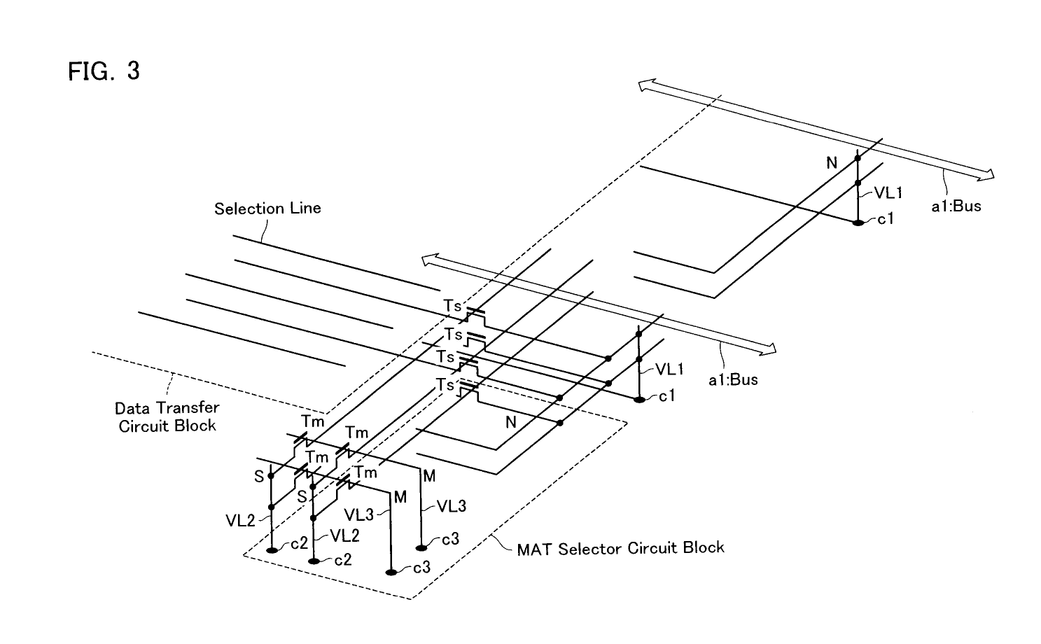

FIG. 3 is a perspective view showing a configuration of a selection line driver in the memory system according to the embodiment. In FIG. 3, the specific circuitry in the circuit block is omitted.

The circuit blocks on the semiconductor substrate are roughly divided into two. The first is a data transfer circuit block and the second is a MAT selector circuit block. The data transfer circuit block is a circuit group that occupies the part beneath the stacked MATs as shown in FIG. 3 and executes selection line decoding and data processing. In addition, the MAT selector circuit block is operative to select among MATs and make access thereto. The data transfer circuit block is a circuit associated with data write and data read. It includes control logic circuits such as a sense amp SA and a roughest selection line decoder. The MAT selector circuit block is a part for determining which MAT of the stacked MATs should be under action of the data transfer circuit block. The MAT selector circuit block passes signals therethrough to the selected MAT and brings other non-selected MATs into the floating state. The MAT selector circuit block is arranged at a location, around the corner of a MAT, closest to each MAT and having an extreme symmetry. The TILE is a structure of plural MTAs stacked.

As shown in FIG. 3, selection lines on each MAT are driven, for example, from one side and the opposite side of the MAT alternately at every line. Hereinafter, seen from the MAT, a side, on which a selection line driver for driving an access selection line is located, is referred to as an “access side” and the opposite side as a “non-access side”. In addition, the relations mutually seen from the access side and the non-access side may also be referred to as “facing sides”. In a word, when a certain selection line is driven from a selection line driver on one side of the MAT, a selection line adjacent to that selection line is driven from a selection line driver on the facing side. In plural selection lines driven from selection line drivers on one side, a certain number of grouped adjacent selection lines configure a selection line group. At every selection line group, a driver signal N supplied from selection line drivers to selection lines is common. The driver signal N is supplied to selection lines via vertical lines along the wall of the TILE. The number of vertical lines decides the number of lines locatable on the semiconductor substrate. In FIG. 3, the lines located on the semiconductor substrate are grouped into buses and shown by the thick two-way arrows a1.

Gate signals to TFTs connected to selection lines in the selection line group are independent of each other. The driver signal N is branched in accordance with on/off of TFTs and supplied to a certain selection line. In the case of FIG. 3, the driver signal N is generated at a peripheral circuit on the semiconductor substrate, then sent via a connection portion c1 with a vertical line VL1 on the peripheral circuit and via the vertical line VL1, then branched at TFTs (Ts), and supplied to a certain selection line. In the case of FIG. 3, gate signals S to TFTs (Ts) are common to plural selection line groups in the MAT. Thus, the driver signal N is supplied to selection lines simultaneously at every MAT by the number of selection line groups contained in the MAT.

The gate signal to TFTs is generated at a circuit block around the corner of the TILE on the semiconductor substrate. The gate signal is used to control the selection among selection line groups in the MAT and the selection among MATs in the TILE. Therefore, the access circuit requires TFTs for selecting among selection line groups in the MAT or TFTs for selecting among MATs in the TILE. FIG. 3 shows an example of TFTs (Tm) provided in the access circuit for selecting among MATs. The gate signal S to TFTs (Ts) connected to selection lines is generated at the MAT selector circuit block provided on the semiconductor substrate, then sent via a connection portion c2 with a vertical line VL2 on the MAT selector circuit block, via the vertical line VL2, and via TFTs (Tm) for selecting among MATs, and supplied to the gates of TFTs (Ts). The gate signal M to TFTs (Tm) for selecting among MATs is generated at the MAT selector circuit block provided on the semiconductor substrate, then sent via a connection portion c3 with a vertical line VL3 on the MAT selector circuit block, and via the vertical line VL3, and supplied to the gates of TFTs (Tm).

The following description is given to a simple example of the layout of TFTs formed on the MAT.

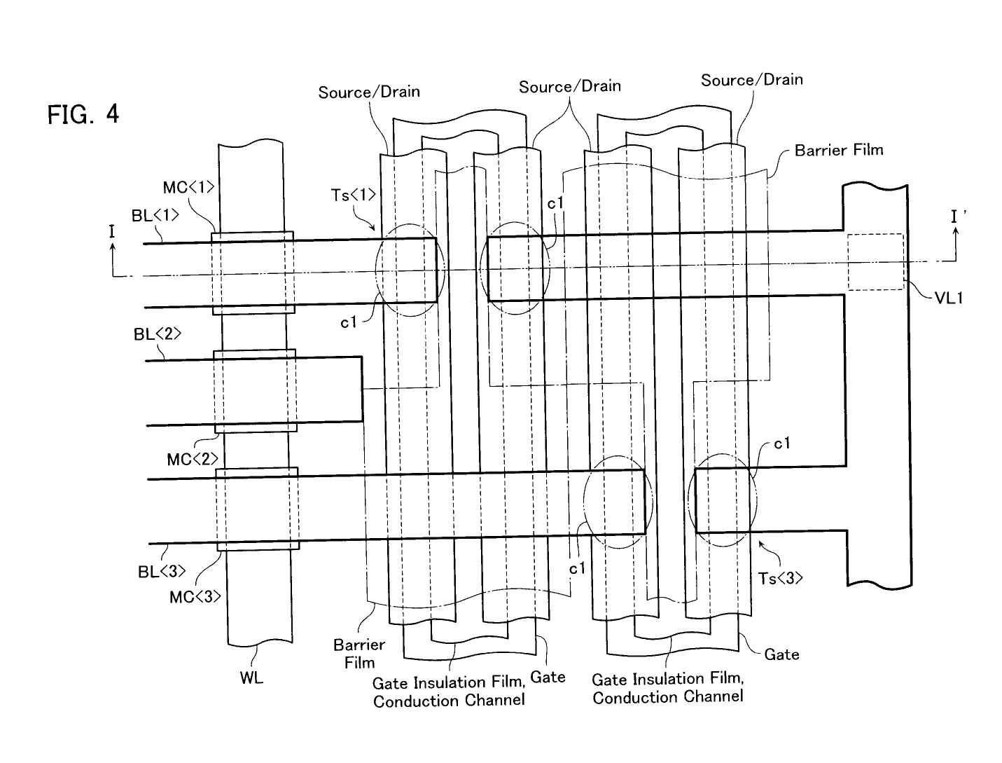

FIG. 4 is a diagram showing a layout example of TFTs on a MAT in the memory system according to the embodiment.

This layout shows part of a selection line driver using a TFT. This TFT has a conductive channel using an oxide semiconductor containing an oxide of In, Ga, Zn or the like, or using carbon nanotubes. The TFT herein shown has a structure of a metal layer turning to a gate located beneath the conductive channel (close to the semiconductor substrate). This structure is referred to as a bottom gate structure. Different from the conventional transistor formed on the semiconductor substrate, it is expected that a new flexibility of the layout can be obtained because the gate locates beneath.

FIG. 4 shows a layout of two TFTs provided between selection line drivers and selection lines to branch the driver signal N. In this layout, three vertically aligned CP cells MC<1>-<3>, two laterally aligned TFTs (Ts)<1> and <3>, and a vertical line VL1 are shown from left to right in FIG. 4.

The CP cells MC<1>-<3> are formed at the intersections of the word line WL extending in the vertical direction in FIG. 4 and the bit lines BL<1>-<3> formed on the word line WL and extending in the lateral direction in FIG. 4. The bit lines BL<1>-<3> are driven from the selection line drivers on the facing sides of the MAT alternately as described above. In a word, the selection line drivers shown in FIG. 4 are selection line drivers for driving the bit lines BL<1> and <3>. TFTs (Ts)<1> and <3> each have a gate extending in the vertical direction, a gate insulation film formed on the gate and extending in the vertical direction, a conduction channel formed on the gate insulation film and extending in the vertical direction, and a source/drain formed on the conduction channel and extending in the vertical direction. The conduction channel is formed so as to have a narrower width than the width of the gate. The source/drain is partly extended to the conduction channel. In addition, from the left end of the source to the right end of the drain, it is formed to cover the left end through the right end of the gate. The source/drain is selectively connected to a bit line BL. Therefore, at the time of forming the bit lines BL, a barrier film is formed in a shape as shown by a chain line in FIG. 4. In addition, a selective contact with the source/drain is provided on the bit line BL as shown by a two-dot chain line circle c1 in FIG. 4. The vertical line VL1 is connected to the bit lines BL<1> and <3> in common. In the case of this layout, the conductive channel on the gate can be formed long in the vertical direction and thus the TFT gate width can be extended.

Next, the layout in FIG. 4 is described on the forming steps.

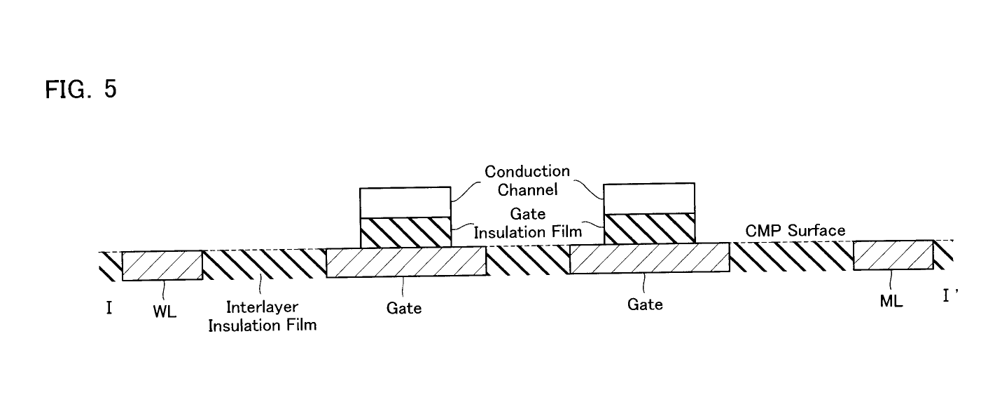

FIGS. 5-10 are cross-sectional views showing steps of forming the selection line driver in order of step in the memory system according to the embodiment. FIGS. 5-10 are cross-sectional views seen in the direction I-I′ in FIG. 4.

Initially, as shown in FIG. 5, a metal line ML is formed on an interlayer insulation film on the semiconductor substrate. The metal line ML is turned to word lines WL, TFT gates and connection portions of vertical lines VL1. Then, CMP or the like is used to planarize the surface thereof. Thereafter, a layer turning to a gate insulation film and a layer turning to a conduction channel are stacked on the interlayer insulation film, the word lines WL, the gates and the metal line ML. Then, RIE or the like is used in patterning the layer turning to the gate insulation film and the layer turning to the conduction channel in accordance with the TFT shape. At that time, patterning is executed such that the surfaces of the word lines WL and the metal line ML are exposed. Thus, the gate insulation film and the conduction channel can be formed. The layer turning to the conduction channel is formed of a material capable of achieving the TFT function, such as an oxide semiconductor and carbon nanotubes.

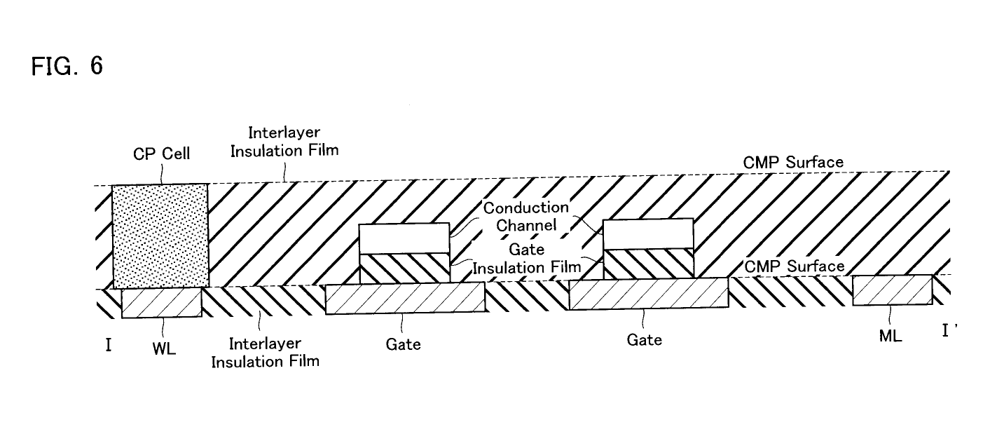

Subsequently, as shown in FIG. 6, a layer turning to CP cells containing variable resistance elements is stacked on the word lines WL. Then, RIE or the like is used in pattering the layer turning to CP cells in accordance with the CP cell shape, thereby forming CP cells. Thereafter, an interlayer insulation film is filled so as to cover the interlayer insulation film, the gate, the gate insulation film, the conduction channel and the metal line ML. Then, CMP or the like is used to planarize the upper surface of the interlayer insulation film until the surface of the CP cell appears.

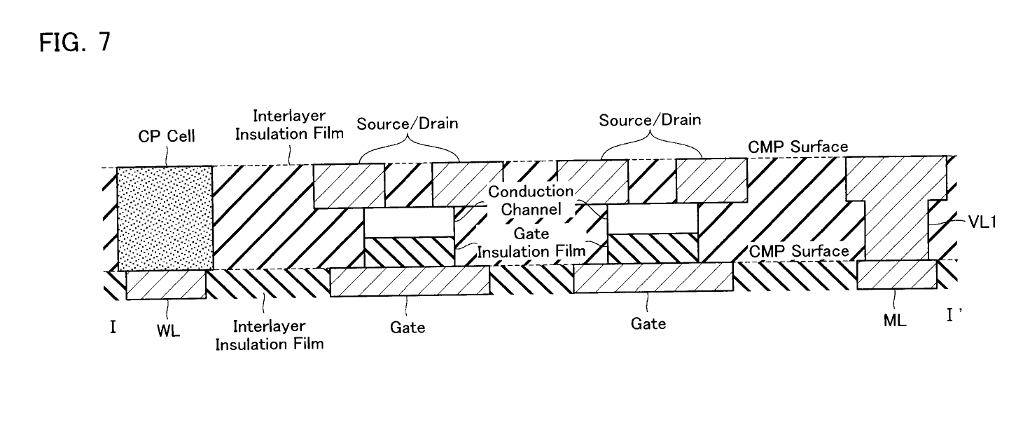

Subsequently, as shown in FIG. 7, a damascene groove having the bottom partly containing the end of the conductive channel is formed in the interlayer insulation film. In conjunction therewith, a damascene groove is formed also on the metal line ML. Further, a dual damascene method or the like is used to deepen the damascene groove down to the surface of the metal line ML. Thereafter, a metal film is filled in these damascene grooves. Thereafter, CMP or the like is used to remove bridges between portions of the metal film and planarize the surface of the metal film so as to turn the metal film into isolated metal lines. Thus, the source/drain and the vertical line VL1 can be formed.

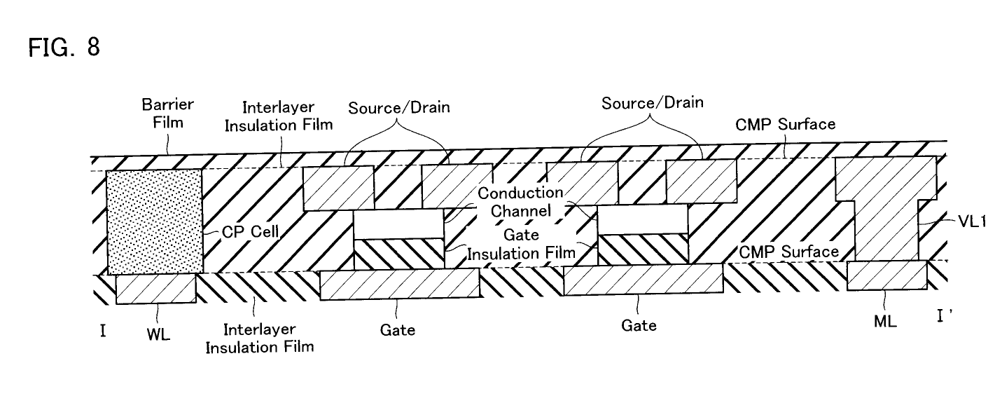

Subsequently, as shown in FIG. 8, a layer turning to a barrier film for selective connection of the bit line BL is stacked on the interlayer insulation film, the CP cell, the source/drain and the vertical line VL1. The layer turning to the barrier film serves as a stopper at the time of RIE and damascene groove formation.

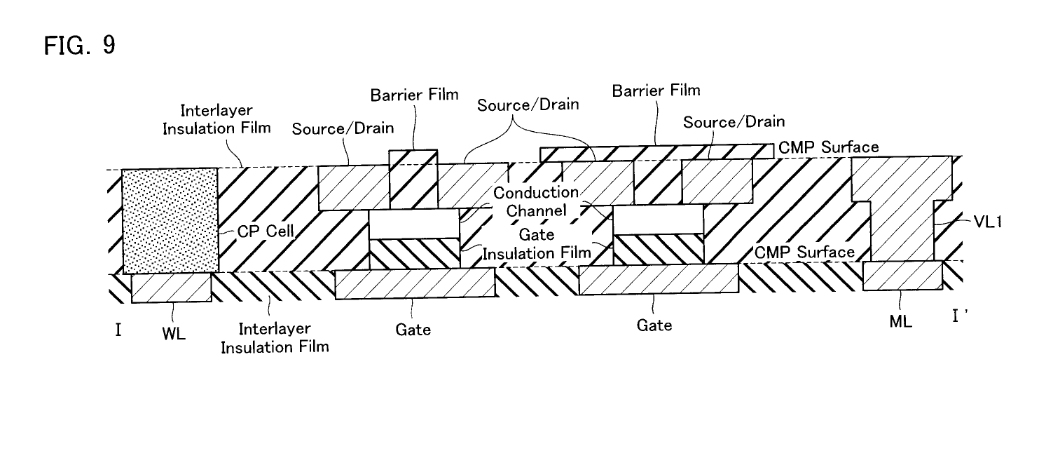

Subsequently, as shown in FIG. 9, RIE or the like is used in patterning the layer turning to the barrier so as to cover the connection-unintended source/drain. At that time, the surfaces of the connection-intended source/drain and the CP cell are exposed, thereby forming the barrier film.

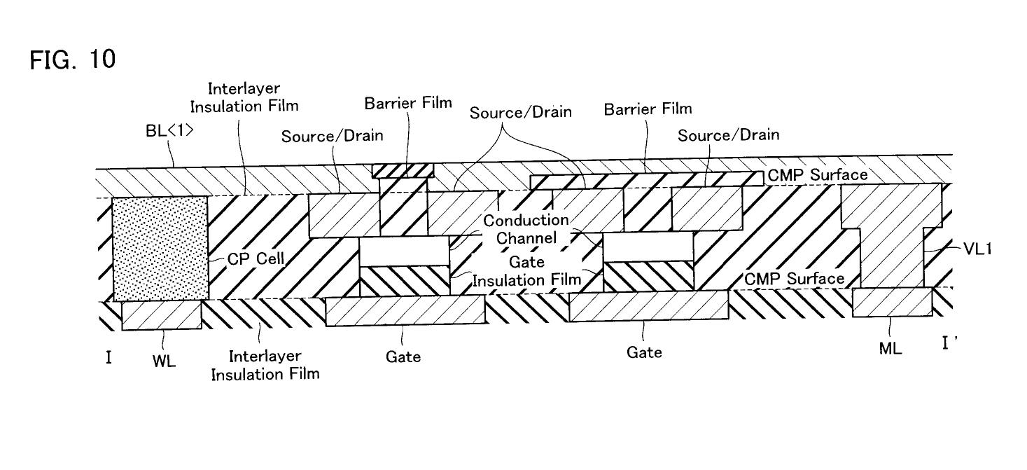

Subsequently, as shown in FIG. 10, a bit line BL<1> is formed on the interlayer insulation film, the CP cell, the source/drain and the vertical line VL1. The bit line BL<1> can be formed, for example, by filling a metal film after damascene groove formation and then removing undesired portions. It can be also formed by using RIE or the like in patterning a layer turning to the bit line BL<1> after it is stacked. The use of any method makes it possible to form the required bit line BL<1> because the portions of the TFT source/drain not connected to the bit line BL<1> are covered with the barrier film. Then, CMP or the like is used to planarize the surfaces of the interlayer insulation film and the bit line BL<1>. In this connection, the forming step in FIG. 10 is the pre-process of the forming step in FIG. 5.

In forming a cell array including plural MATs stacked, the forming steps in FIGS. 5-10 are repeated by the number of stacked MATs. In the case of a cell array structured to share a selection line between vertically adjacent MATs, however, it is required to repeat the above forming steps while changing between the layout of the MAT in the row direction and that in the column direction every time one layer is stacked.

The following description is given to an example of access operation to which a TFT-used selection line driver is applicable. The method of access operation herein described is characterized in that a selection line driver is artificially regarded off when a selection line falls within a certain potential range. In this case, the selection line is brought into the floating state isolated from external voltage supply. Therefore, this method is hereinafter referred to as a pseudo-floating access method (hereinafter abbreviated as a “pseudo-FA method”).

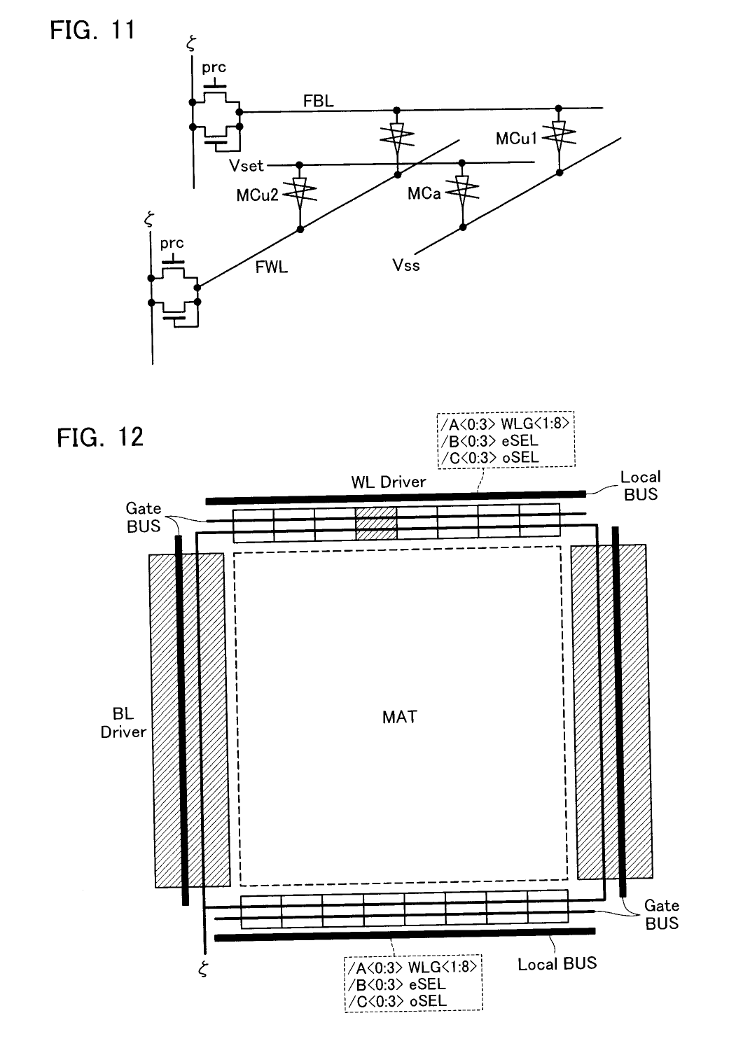

FIG. 11 is a diagram illustrative of access operation in a pseudo-FA method in the memory system according to the embodiment.

The access operation in the pseudo-FA method just requires relatively simple controls, for example, setting the anode and cathode of a memory cell MC on the equipotential. Accordingly, the circuitry of the selection line driver can be simplified. In addition, even in the presence of a short fault memory cell MC (hereinafter also referred to as a “fault cell”), it is not required to execute special potential setting for the purpose of preventing it from exerting influences on access to other memory cells MC. Therefore, it is possible to simply realize a redundancy system for fault cells MC. From these points, the pseudo-FA method is a method of access operation easily put to practical use as is said. Namely, the presence/absence of a short fault cannot be seen unless a fault cell MC in the MAT of the cell array is accessed.

Selection lines in the MAT are provided with an initial potential ζ. An Nch transistor having a threshold voltage Vth and provided in a selection line driver is used so that, even if the potential on the selection line set at the potential ζ varies within a range of ±Vth, it is substantially isolated from the power supply ζ. Thus, non-access selection lines stay at self-aligned potentials almost determined by the situation of memory cells and so forth if they fall within a range of ζ±Vth. Therefore, it is possible to utilize the advantage in the pseudo-FA method over variations in memory cells MC in the MAT.

Namely, even if the potentials on non-access selection lines vary in accordance with coupling with adjacent selection lines and so forth, the amounts of variations can be suppressed almost within a range of ±Vth. Therefore, even a large disturbance cannot change the states of non-access cells MC.

For providing selection lines FBL and FWL in the MAT with the potential ζ, it is sufficient to raise a signal prc in FIG. 11 up to the potential ζ+Vth or above to directly supply the potential ζ to all selection lines.

When the signal prc is returned to the potential ζ before access, the power supply ζ is connected to selection lines (“FBL” and “FWL” shown in FIG. 11) through diode-connected Nch transistors having a threshold voltage Vth.

The selection line connected to a fault cell MC is always suppressed to the potential ζ±Vth unless it is accessed. Accordingly, it exerts no influence on other memory cells MC in the same MAT.

When the selection line connected to a fault cell MC is accessed, a large current flows therein. Accordingly, it is possible to specify a fault. This makes it possible to exert control such that the selection line is not accessed hereinafter. These are all executed at a control circuit outside the MAT without the need for special ideas applied to selection line drivers in the MAT accordingly.

In FIG. 11, a memory cell MCa is accessed. For making the above-described pseudo-FA method function, it is important to keep cell current in non-access cells MCu1 and MCu2 at a lower value than leakage current on application of a reverse bias. Therefore, it is required to exhibit the same high resistance state as the state of non-access cells MCu1 and MCu2 reverse-biased so that an Nch transistor having a threshold voltage Vth and connected to the power supply ζ functions effectively.

The following description is given to an example of part of selection line drivers formed on the MAT contained in a TILE. The TILE is a structure of plural stacked MTAs.

FIG. 12 is a diagram showing functional blocks of the TILE and peripheral circuits in the memory system according to the embodiment. In FIG. 12, the TILE is shown almost square though the TILE may be rectangular, for example.

The configurations of selection line drivers located around the MAT are almost the same to both bit lines BL and word lines WL and no difference presents among MATs. On access operation, however, bit lines BL are accessed simultaneously plural in parallel while word lines WL are accessed only one per MAT. Therefore, bit line drivers and word line drivers on the TILE have a difference in decoders.

In FIG. 12, buses of signal lines required to decode access-targeted selection lines include buses located on each MAT and similarly configured for bit lines BL and word lines WL, which are shown as gate buses. In addition, selection line drivers for driving access selection lines are hatched. As described above, bit lines BL are accessed simultaneously plural in parallel and accordingly selection line drivers for bit lines BL are totally hatched. On the other hand, word lines WL are accessed only one per MAT and accordingly only one selection line driver is hatched.

The hatched selection line driver for the word line WL further executes decoding to make access to a certain word line WL. This decoder is formed not on the MAT but on the semiconductor substrate. The signal from the decoder is supplied to each selection line driver via a local bus. An example of signals required in the decoder includes /A<0:3>, /B<0:3>, /C<0:3>, eSEL, oSEL and WLG<1:8> as shown. These signals have respective roles described later. In addition, each selection line driver is supplied with a voltage from a common power supply.

As described above, the potentials on selection lines are set by selection line drivers. For increasing the cell share, it is required to align these selection line drivers at a high density around the MAT. Therefore, a simplified layout of selection line drivers and a reduced space become important.

The following description is given to a BL dry circuit block contained in the selection line driver. The BL dry circuit block herein described is configured for use in the bit line driver though it is also applicable to the word line driver. This is described later.

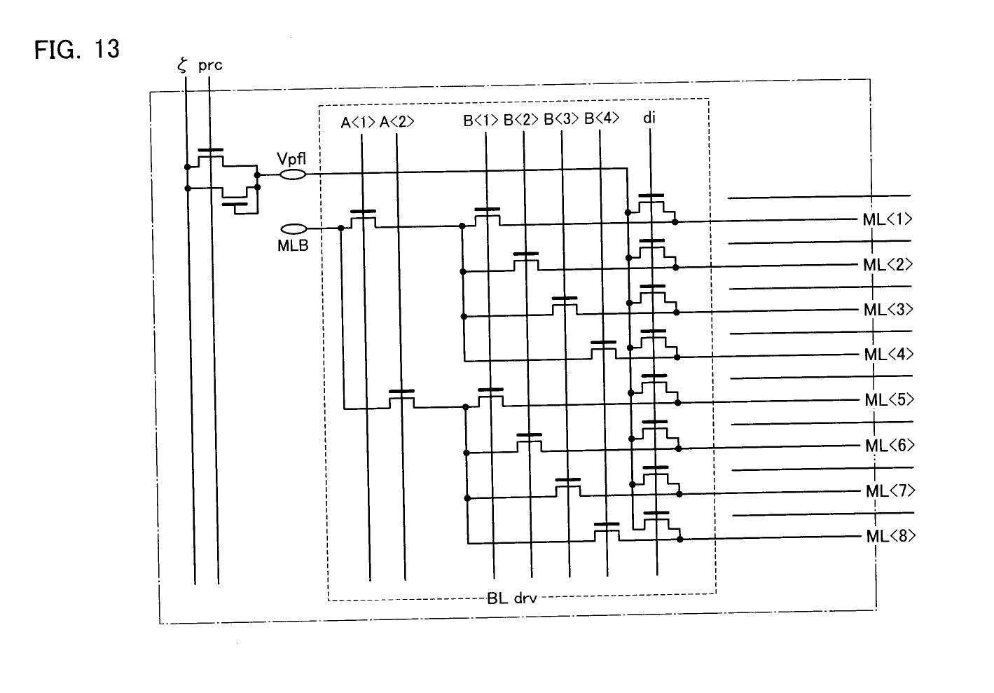

FIG. 13 is a circuit diagram of a BL dry circuit block in the memory system according to the embodiment. In FIG. 13, a range surrounded by a dashed line defines the BL dry circuit block, which is a part formed on each MAT.

FIG. 13 is a circuit diagram in the case when BL dry circuit blocks are provided one by one on the access side and the non-access side at every 16 selection lines. In a word, the number of selection lines taken charge by one BL dry circuit block is equal to eight, and the remaining eight selection lines are taken charge by the facing-side BL dry circuit block. ML<1>-<8> shown in FIG. 13 indicate selection lines driven by one BL dry circuit block. In addition, Vpfl and MLB in FIG. 13 indicate portions connected to vertical lines, through which signals Vpfl and MLB pass, for connecting each line in each MAT to the BL dry circuit block. A “TILE” requires BL dry circuit blocks by the number of stacked MATs.

It is a signal di that decides whether selection lines ML<1>-<8> should be diode-connected to the power supply ζ or not. When the signal di is turned to ‘H’ and the signal prc is set to the potential ζ, the potential on the selection line ML varies up/down from ζ by the threshold voltage Vth to configure a diode connection of a transistor that hardly allows current to flow in the selection line ML. The signal prc is turned to ‘H’ so that the selection line ML can be set to the potential ζ. When selection lines are brought into the pseudo-floating state, and when selection lines are set to the potential ζ, address signals A<1>-<2> and B<1>-<4> for selecting selection lines are all turned to ‘L’ to isolate selection lines ML from the signal line MLB.

When an access selection line is driven, initially, the signal di is turned to ‘L’ to isolate selection lines from the power supply ζ. Subsequently, a combination of the signals A<1>-<2> and B<1>-<4> is used to select which selection line ML of selection lines ML<1>-<8> is determined as an access selection line. The access selection line is connected to a signal line MLB. When the signals A<1>-<2> and B<1>-<4> are supplied to all BL dry circuit blocks in common, selection lines can be selected simultaneously one from every BL dry circuit block. In contrast, when the signals A<1>-<2> and 13<1>-<4> are supplied to every group of BL dry circuit blocks separately, the number of simultaneously selectable selection lines can be adjusted.

The signal MLB is a signal for driving the bit line BL and monitoring the state of the memory cell MC. It is supplied to a sense amp and an access circuit.

The signal line MLB is provided with the set potential Vset, the ground potential Vss and the potential ζ in accordance with data to be written in the memory cell MC. The simultaneously selected bit lines BL are provided with the potentials Vset, Vss and ζ individually and simultaneously.

The word lines WL of selection lines are selected only one per MAT. Therefore, when the selection line driver for the word line WL on the access side selects one BL dry circuit block to supply the signal MLB, the above-described BL dry circuit block can also be applied to the driver for the word line WL.

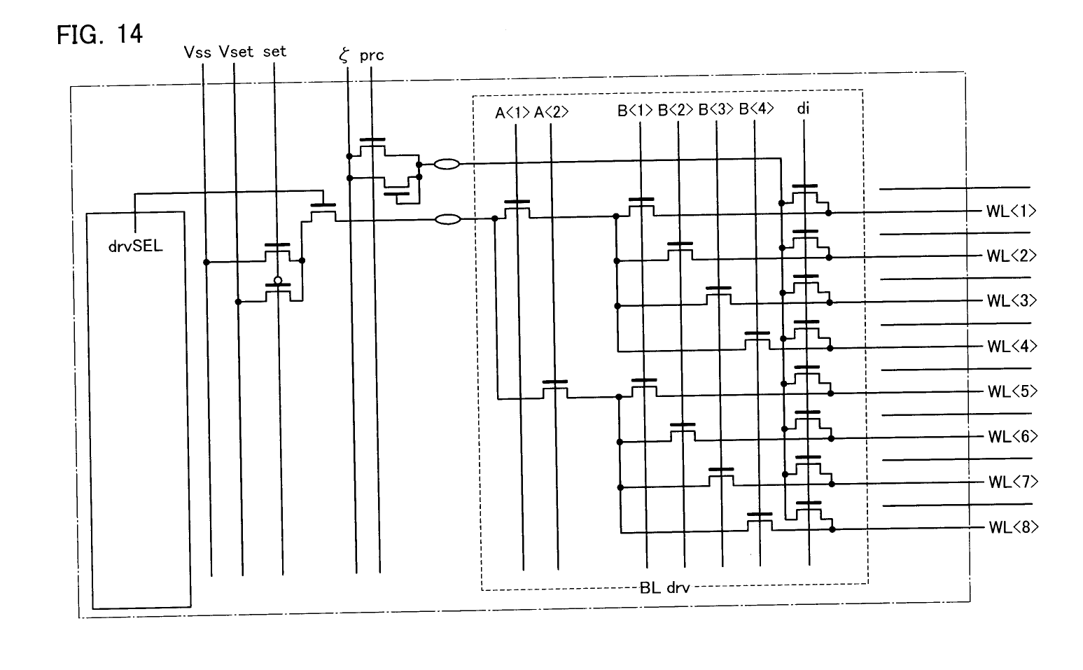

FIG. 14 is a circuit diagram of a selection line driver for the word line in the memory system according to the embodiment. A circuit surrounded by a chain line in the figure shows the selection line driver for the word line WL.

The circuit shown in FIG. 14 is configured to include the BL dry circuit block shown in FIG. 13 and additionally a drvSEL circuit block operative to select one BL dry circuit block.

The outputs of the BL dry circuit block lead to word lines WL<1>-<8>. This BL dry circuit block provides the access word line WL with the ground potential Vss or the set potential Vset. This switching is executed by a signal, set. This signal, set, is used to control an Nch transistor and a Pch transistor to supply the ground potential Vss or the set potential Vset to the BL dry circuit block from the drvSEL circuit block via a switch transistor. The switch transistor is on/off controlled in accordance with a signal drvSEL provided from the drvSEL circuit block.

The following description is given to the drvSEL circuit block, that is, a circuit operative to select one word line WL from the MAT.

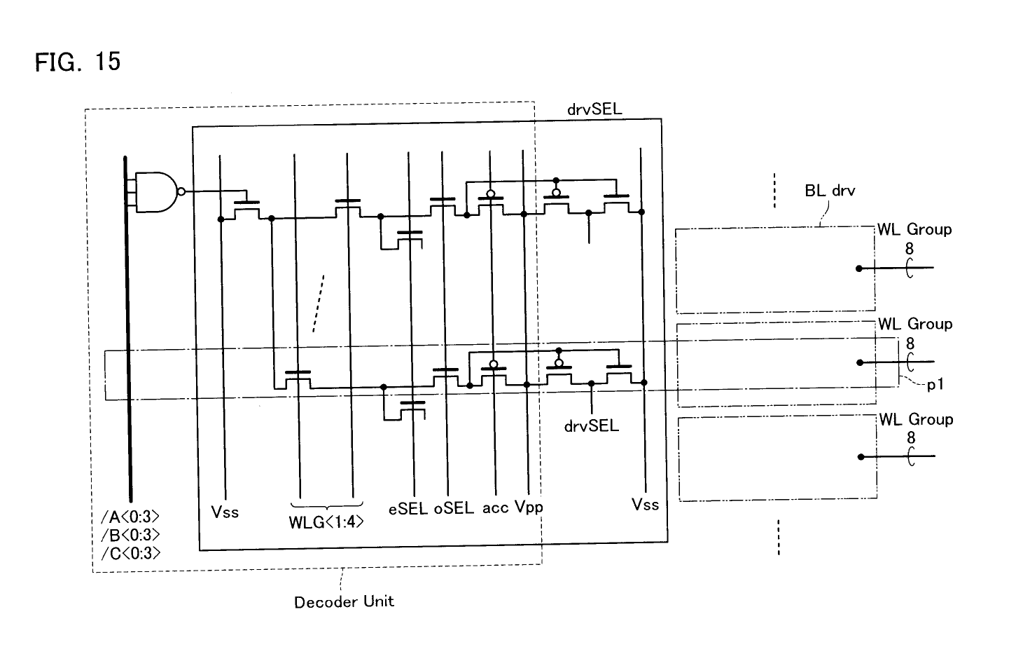

FIG. 15 is a circuit diagram of the drvSEL circuit block in the memory system according to the embodiment.

The output from this drvSEL circuit block is the signal drvSEL as described above. This signal drvSEL turns to ‘L’ so as not to select the BL dry circuit block. It brings the input of the BL dry circuit block into the floating state. The drvSEL circuit block, the signal drvSEL, receives a signal indicative of the decoding state, on gates of a Pch transistor and an Nch transistor, and connects the signal drvSEL to the ground potential Vss or to the power supply of a potential Vpp higher than the set potential Vset.

As shown by the dashed-line square in FIG. 15, part of the drvSEL circuit block and a NAND circuit configure a decoder unit. The decoder unit receives a signal, acc, for precharging to the supply potential Vpp, signals eSEL, oSEL and WLG<1:4> for discharging the supply potential Vpp, and the output from the NAND circuit operative to decode address signals /A<0:3>, /B<0:3> and /C<0:3>. Namely, this decoder unit uses the signals eSEL, oSEL and WLG<1:4> to select one of eight BL dry circuit blocks. It also decodes the signals /A<0:3>, /B<0:3> and /C<0:3> to select one drvSEL circuit block. Therefore, in the case of the example shown in FIG. 15, one side of the MAT is configured by 8×4³=512 word line groups of eight word lines WL. At the access-side driver operative to select an access word line WL, the signal acc turns to ‘H’ to stop precharging to the decoder unit. The decoder unit includes a serial circuit p1 of plural transistors each controlled by the signal eSEL or oSEL, one of the signals WLG<1:4>, or the output from the NAND circuit. Via this serial circuit p1, the charge on a precharge node is discharged to the ground potential Vss. In this connection, p1 shown by a chain line is coincident with a chain line shown in FIG. 14.

Finally, a description is given to an example of the layout of the BL dry circuit block provided at every MAT.

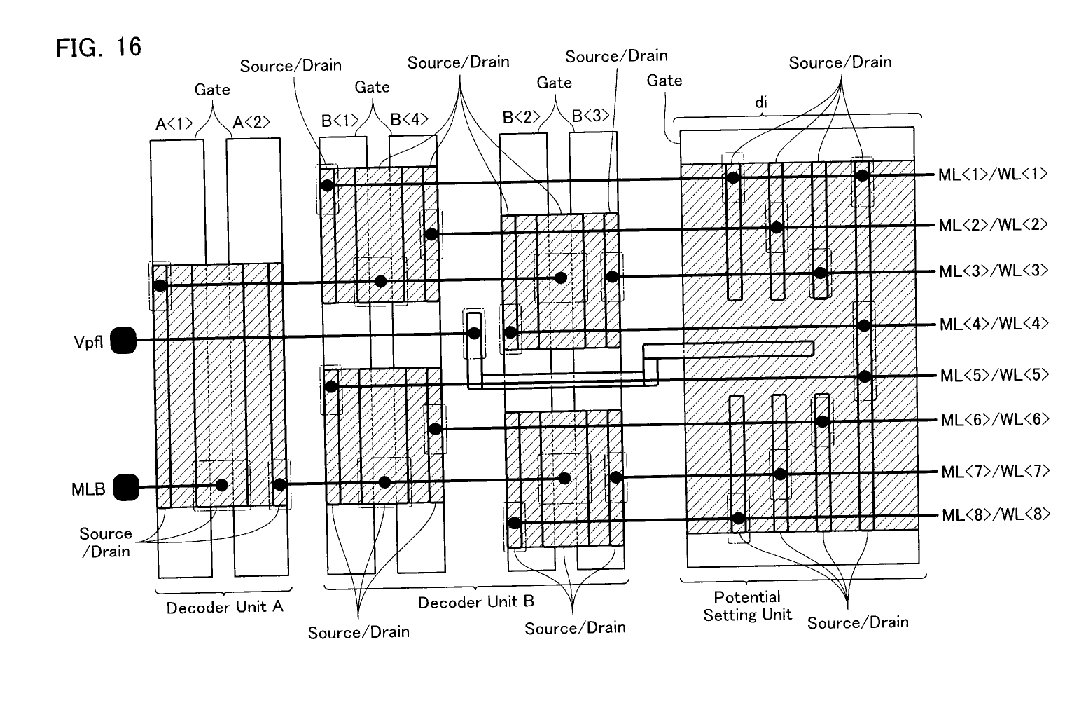

FIG. 16 is a diagram showing a layout of the BL dry circuit block in the memory system according to the embodiment. In FIG. 16, a hatched part shows a conductive channel of a TFT and a chain-lined encircled range shows an aperture in the barrier film.

Parts of selection line drivers are simply configured of TFTs and formed on each MAT for the purposes of reducing the area occupied by peripheral circuits in the MAT to prevent the scale of peripheral circuits from depending on the number of stacked MATs, and reducing vertical lines to circuits on the semiconductor substrate as few as possible so that the circuits and bus lines on the semiconductor substrate can be configured beneath the TILE freely.

Selection lines are formed at the minimum line width and intervals. It is lithographically desired to allow transistors in peripheral circuits to be connected to selection lines without bending the selection lines. TFTs having a bottom gate structure make it possible.

In the case of the layout of the BL dry circuit block shown in FIG. 16, a decoder unit A, a decoder unit B and a potential setting unit are arranged in order from left to right in FIG. 16.

The layout in the case shown in FIG. 16 includes conductive channels of plural TFTs composed of an oxide semiconductor and lines turning to gates of TFTs extending in the vertical direction and formed beneath the conductive channels. These gates are formed also in other circuits in common along the periphery of the MAT. In addition, sources/drains of plural TFTs composed of a metal are formed between the gates and the conductive channels. For making these sources/drains contact with lines ML/WL extending straight from the MAT, apertures are formed through the barrier film serving as a stopper. Thus, selection lines make contact with the gates or the sources/drains. In a further left part away from the decoder unit A, connection portions are formed for vertical lines, which connect between MATs, extend in the vertical direction, and allow the signals Vpfl and MLB to pass therethrough.

The characteristics of the TFT having the bottom gate structure include one associated with a conduction path that can be led out of the TFT if the source/drain metal film is arranged appropriately on the conduction channel. This characteristic can be found remarkably in the layout of the potential setting unit at the rightmost part in FIG. 16. When the conduction channel is off, these conduction paths are isolated.

As described above, the embodiment uses TFTs to configure parts of selection line drivers and arranges them on the MAT, thereby constructing a memory system including a three-dimensionally structured cell array having a high cell share.

### [Others]

While the embodiments of the present invention have been described, these embodiments are presented by way of example and are not intended to limit the scope of the invention. These novel embodiments can be implemented in a variety of other forms, and various omissions, substitutions and changes can be made without departing from the spirit of the invention. These embodiments and variations thereof would fall within the scope and spirit of the invention and also fall within the invention recited in claims and equivalents thereof.

What is claimed is:

1. A memory system, comprising:
a cell array including plural unit cell arrays stacked, each unit cell array containing plural first lines, plural second lines intersecting said plural first lines, and plural memory cells provided at the intersections of said plural first lines and said plural second lines; and
an access circuit operative to write data in said memory cell,
wherein said access circuit partly has a first part formed at the same height as that of a certain unit cell array in the stacking direction of said plural unit cell arrays and on the periphery of said certain unit cell array.

2. The memory system according to claim 1, wherein said first part of said access circuit includes a thin film transistor.

3. The memory system according to claim 2, wherein said thin film transistor of said access circuit is formed between said plural first lines and said plural second lines in said certain unit cell array in said stacking direction.

4. The memory system according to claim 2,
wherein said cell array is formed above a semiconductor substrate, and
said thin film transistor of said access circuit has a gate and a conductive channel, wherein said gate is formed closer to said semiconductor substrate than said conductive channel.

5. The memory system according to claim 4,
wherein said thin film transistor of said access circuit has a source and a drain formed on said conductive channel, and
said plural first lines in said certain unit cell array are each connected to said source or said drain.

6. The memory system according to claim 5,
wherein said first part of said access circuit includes a barrier film between said source and drain of said thin film transistor and said plural first lines in said certain unit cell array, and
said barrier film has an aperture formed in a connection portion between said source or drain and said first line.

7. The memory system according to claim 2, wherein said thin film transistor of said access circuit has a conductive channel formed of an oxide semiconductor or carbon nanotubes.

8. The memory system according to claim 1, wherein said memory cell includes a variable resistance element.

9. A memory system, comprising:
a cell array including plural unit cell arrays stacked, each unit cell array containing plural first lines, plural second lines intersecting said plural first lines, and plural memory cells provided at the intersections of said plural first lines and said plural second lines; and
an access circuit operative to write data in said memory cell,
wherein said access circuit has a first part inherent in a certain unit cell array, said first part formed at the same height as that of said certain unit cell array in the stacking direction of said plural unit cell arrays and on the periphery of said certain unit cell array.

10. The memory system according to claim 9, wherein said first part of said access circuit includes a thin film transistor.

11. The memory system according to claim 9, wherein said thin film transistor of said access circuit is formed between said plural first lines and said plural second lines in said certain unit cell array in said stacking direction.

12. The memory system according to claim 10,
wherein said cell array is formed above a semiconductor substrate, and
said thin film transistor of said access circuit has a gate and a conductive channel, wherein said gate is formed closer to said semiconductor substrate than said conductive channel.

13. The memory system according to claim 12,
wherein said thin film transistor of said access circuit has a source and a drain formed on said conductive channel, and
said plural first lines in said certain unit cell array are each connected to said source or said drain.

14. The memory system according to claim 13,
wherein said first part of said access circuit includes a barrier film between said source and drain of said thin film transistor and said plural first lines in said certain unit cell array, and
said barrier film has an aperture formed in a connection portion between said source or drain and said first line.

15. The memory system according to claim 10, wherein said thin film transistor of said access circuit has a conductive channel formed of an oxide semiconductor or carbon nanotubes.

16. The memory system according to claim 9, wherein said memory cell includes a variable resistance element.

17. A method of manufacturing a memory system, said memory system comprising
a cell array including plural unit cell arrays stacked, each unit cell array containing plural first lines, plural second lines intersecting said plural first lines, and plural memory cells provided at the intersections of said plural first lines and said plural second lines, and
an access circuit operative to write data in said memory cell,
wherein said access circuit partly has a first part containing a thin film transistor, said method comprising:
forming a gate of said thin film transistor, at the same height as that of a certain unit cell array in the stacking direction of said plural unit cell arrays and on the periphery of said certain unit cell array, after forming said second lines and before forming said first lines;
forming a gate insulation film of said thin film transistor on said gate;
forming a conductive channel of said thin film transistor on said gate insulation film; and
forming a source and a drain of said thin film transistor on said conductive channel.

18. The method of manufacturing a memory system according to claim 17, further comprising forming a barrier film having an aperture for selectively connecting said plural first lines to said source or drain of said thin film transistor, after forming said source and drain of said thin film transistor and before forming said plural first lines.

19. The method of manufacturing a memory system according to claim 17, where said conductive channel is formed of an oxide semiconductor or carbon nanotubes.

20. The method of manufacturing a memory system according to claim 17, further comprising:
forming an interlayer insulation film on said conductive channel, after forming said conductive channel of said thin film transistor and before forming said source and drain of said thin film transistor;
forming a damascene groove at the time of forming said source and drain, said damascene groove having the bottom partly containing the end of said conductive channel; and
filling said damascene groove with a metal film.
